(19) United States
(12) Patent Application Publication
(10) Pub. No.: US 2025/0247646 A1
(43) Pub. Date: Jul. 31, 2025

(54) AUTOMATIC LOBE GAIN ADJUSTMENT FOR ARRAY MICROPHONES

(71) Applicant: Shure Acquisition Holdings, Inc., Niles, IL (US)

(72) Inventors: Dusan Veselinovic, Chicago, IL (US); Bijal Joshi, Elk Grove Village, IL (US); Yanchao Liu, Northbrook, IL (US)

(21) Appl. No.: 19/034,314

(22) Filed: Jan. 22, 2025

Related U.S. Application Data
(60) Provisional application No. 63/625,015, filed on Jan. 25, 2024.

(51) Int. Cl. H04R 3/00; H04R 1/40

(52) U.S. Cl. CPC H04R 3/005; H04R 1/406; H04R 2430/01

(57) ABSTRACT

Systems and methods are provided for automatically adjusting lobe gain by receiving, from at least one microphone, sound location information for an audio source detected by the at least one microphone; calculating a distance between the audio source and the at least one microphone based on the sound location information, a first height associated with the at least one microphone, and a second height associated with the audio source; determining, based on the distance, a gain value for an audio pickup lobe directed towards the audio source by the at least one microphone; and applying the gain value to an audio channel of the at least one microphone, the audio channel configured to receive audio signals captured using the audio pickup lobe.

### CROSS-REFERENCE

This application claims priority to U.S. Provisional Application No. 63/625,015, filed on Jan. 25, 2024, the contents of which are incorporated by reference herein in their entirety.

### TECHNICAL FIELD

This disclosure generally relates to array microphones with automatically adjustable lobes, and more specifically, to automatic lobe gain adjustment based on detected talker distance information.

### BACKGROUND

In audio environments such as conference rooms, boardrooms, and other meeting spaces, array microphones can be used to capture sounds produced by various audio sources by directing beamformed microphone lobes (or audio pick-up patterns) towards the desired audio sources. The audio sources may include human speakers, or talkers, for example. Some array microphones use microphone information and algorithms to estimate the position of an audio source relative to the microphone. For example, a beamforming array microphone can be used to determine or obtain coordinates (e.g., localization coordinates) that represent the estimated location of sound generated by an audio source detected by the microphone. Array microphones can also be used to reject unwanted sounds, such as room noise, by steering the microphone lobes away from undesired audio sources. The captured sounds may be disseminated to a local audience in the environment through speakers (for sound reinforcement) and/or to others located remotely (such as via a telecast, webcast, or the like). For example, persons in a conference room may be conducting a conference call with persons at a remote location. Each of the microphone lobes may form a channel, and the sounds captured by the lobes may be input, or received, as multi-channel audio and output, or provided, as a single mixed audio channel.

In general, conferencing devices, and other audio capturing devices that comprise array microphones, are available in a variety of sizes, form factors, mounting options, and wiring options to suit the needs of particular environments. The types of conferencing devices, their operational characteristics (e.g., lobe direction, gain, etc.), and their placement in a particular audio environment may depend on a number of factors, including, for example, the locations of the audio sources, locations of listeners, physical space requirements, aesthetics, room layout, and/or other considerations. For example, in some environments, a conferencing device may be placed on a table or lectern to be near the audio sources and/or listeners. In other environments, a conferencing device may be mounted overhead or on a wall to capture the sound from, or project sound towards, the entire room, for example.

Some existing audio systems ensure optimal audio coverage of a given environment by delineating “audio coverage areas,” which represent the regions in the environment that are designated for capturing audio signals, such as, e.g., speech produced by human speakers or other desired audio. The audio coverage areas may define the spaces where the microphone lobes can be deployed by the array microphones, for example. A given environment or room can include one or more audio coverage areas, depending on the size, shape, and type of environment. For example, the audio coverage area for a typical conference room may include the seating areas around a conference table, while the audio coverage area for a typical classroom may include the space around a blackboard and/or podium at the front of the room. Some audio systems have fixed audio coverage areas, while other audio system are configured to dynamically create audio coverage areas for a given environment based on sound localization information or other data that indicates the location of a detected audio source.

Some array microphones use sound localization information to automatically deploy a microphone lobe in the direction of a newly detected talker located within the designated audio coverage area. Also known as automatic lobe deployment, such techniques typically apply uniform settings (e.g., gain, width, shape, etc.) to each new microphone lobe. However, the geometry of automatically deployed microphone lobes may not be optimal in all environments and situations. For example, in some cases, a default lobe shape steered towards a desired audio source (e.g., a first talker) may be wide enough to also pick up nearby undesirable noise sources (e.g., room noise), while in other cases, the default lobe shape may be too narrow to pick up nearby desirable audio sources (e.g., an adjacent talker). Likewise, the audio settings for automatically deployed lobes may not be optimal in all environments and situations. For example, when the same default lobe gain is applied to all input channels, a talker located closer to the array microphone can appear to have a higher audio level (e.g., volume) than a talker located further away from the array microphone, even though the two talkers speak at approximately the same level.

### SUMMARY

The techniques of this disclosure provide systems and methods designed to, among other things: (1) use detected sound location information to automatically adjust a lobe gain applied to a microphone lobe directed towards the detected audio source; (2) mitigate inaccuracies in a distance estimation for the detected audio source by using array height and talker height information to normalize a radius estimation included in the sound location information; and (3) based on the height information and corrected distance estimation, select an optimal lobe gain for the microphone lobe directed towards the detected audio source.

In an embodiment, a method performed by one or more processors in communication with at least one microphone is provided, the method comprising: receiving, from the at least one microphone, sound location information for an audio source detected by the at least one microphone; calculating a distance between the audio source and the at least one microphone based on the sound location information, a first height associated with the at least one microphone, and a second height associated with the audio source; determining, based on the distance, a gain value for an audio pickup lobe directed towards the audio source by the at least one microphone; and applying the gain value to an audio channel of the at least one microphone, the audio channel configured to receive audio signals captured using the audio pickup lobe.

In another embodiment, a system is provided, the system comprising: at least one microphone configured to detect an audio source and determine sound location information for the audio source; and one or more processors communicatively coupled to the at least one microphone, the one or more processors configured to: receive the sound location information from the at least one microphone; calculate a distance between the audio source and the at least one microphone based on the sound location information, a first height associated with the at least one microphone, and a second height associated with the audio source; determine, based on the distance, a gain value for an audio pickup lobe directed towards the audio source by the at least one microphone; and apply the gain value to an audio channel of the at least one microphone, the audio channel configured to receive audio signals captured using the audio pickup lobe.

In a further embodiment, a non-transitory computer-readable storage medium is provided, the non-transitory computer-readable storage medium comprising instructions that, when executed by one or more processors in communication with at least one microphone, cause the one or more processors to perform: receive, from the at least one microphone, sound location information for an audio source detected by the at least one microphone; calculate a distance between the audio source and the at least one microphone based on the sound location information, a first height associated with the at least one microphone, and a second height associated with the audio source; determine, based on the distance, a gain value for an audio pickup lobe directed towards the audio source by the at least one microphone; and apply the gain value to an audio channel of the at least one microphone, the audio channel configured to receive audio signals captured using the audio pickup lobe.

In another embodiment, a digital signal processing (DSP) component is provided, the DSP component having a plurality of audio channels for respectively receiving a plurality of audio signals captured by at least one microphone, and configured to: receive, from the at least one microphone, sound location information for an audio source detected by the at least one microphone; calculate a distance between the audio source and the at least one microphone based on the sound location information, a first height associated with the at least one microphone, and a second height associated with the audio source; determine, based on the distance, a gain value for an audio pickup lobe directed towards the audio source by the at least one microphone; and apply the gain value to an audio channel of the at least one microphone, the audio channel configured to receive audio signals captured using the audio pickup lobe.

According to various aspects, the DSP component is configured to determine the gain value for the audio pickup lobe by selecting one of a plurality of gain parameters based on the distance, and calculating the gain value based on the selected gain parameter. According to some aspects, the plurality of gain parameters comprises a minimum parameter for setting the gain value to a minimum value, a maximum parameter for setting the gain value to a maximum value, and a medium parameter for using a ratio to set the gain value. According to certain aspects, the DSP component is configured to select one of the plurality of gain parameters by selecting the minimum parameter if the distance is equal to or less than a lower threshold, selecting the maximum parameter if the distance is equal to or greater than an upper threshold, and selecting the medium parameter if the distance is between the lower threshold and the upper threshold. According to one aspect, the DSP component is further configured to determine the lower threshold based on the first height and the second height. According to another aspect, the DSP component is further configured to determine the upper threshold based on the first height.

According to various aspects, the DSP component is further configured to select, based on the sound location information received from the at least one microphone, one of the following actions: deployment of a new audio pickup lobe, resetting of an existing audio pickup lobe, or repositioning of an existing audio pickup lobe; and based on a selection of the deployment action or the resetting action, proceed with calculating the distance.

According to other aspects, the DSP component is further configured to determine, based on the sound location information, a set of coordinates representing an estimated location of the audio source; and use the set of coordinates to direct the audio pickup lobe towards the audio source.

These and other embodiments, and various permutations and aspects, will become apparent and be more fully understood from the following detailed description and accompanying drawings, which set forth illustrative embodiments that are indicative of the various ways in which the principles of the invention may be employed.

### BRIEF DESCRIPTION OF THE DRAWINGS

FIG. 1 is a block diagram of an exemplary audio system comprising an array microphone and one or more audio processors for automatically adjusting lobe gain based on sound location information, in accordance with one or more embodiments.

FIG. 2 is a schematic diagram of an exemplary environment in which the audio system of FIG. 1 can be used, in accordance with one or more embodiments.

FIG. 3A is a graph plotting an exemplary set of parameters that may be used by the audio system of FIG. 1 to automatically adjust lobe gain, in accordance with one or more embodiments.

FIG. 3B is a graph plotting a second set of exemplary parameters that may be used by the audio system of FIG. 1 to automatically adjust lobe gain, in accordance with one or more embodiments.

FIG. 4 is a flowchart illustrating exemplary operations for automatically adjusting lobe gain based on sound location information, in accordance with one or more embodiments.

### DETAILED DESCRIPTION

In general, audio systems can use automatic gain control (or AGC) to provide uniformity in the volume level of all participants (e.g., during a conference call) by ensuring the audio signals sent to listeners at the far end (e.g., remote participants of the conference call) remain at a relatively consistent signal level, despite amplitude changes in the audio signals captured by the microphone at the near end (e.g., local participants of the conference call). The near end signals may have different amplitudes due to variations in the volume or speech level of different talkers or volume variations in the speech of a single talker, for example. AGC can be used to adjust the signal level, or gain, of audio signals in various channels (each of which corresponds to a different lobe), to compensate for the amplitude or speech level differences before the audio signals are combined into a mixed audio output. Traditional AGC techniques train on past audio signals and determine when a gain adjustment is needed by estimating the amplitude of an incoming audio signal and comparing that signal level to those of the past audio samples. If the input amplitude is lower than past levels, the AGC increases the gain applied to the corresponding channel and thus, boosts the incoming signal level. Conversely, if the input amplitude is too high, the AGC can reduce the gain on that channel.

In various situations, the audio signal detected for a talker positioned far away from the microphone may appear to have a lower signal level than that of a talker positioned closer to the microphone, even though the talkers are speaking at the same volume. Similar signal level fluctuations may occur as a single talker moves relative to the microphone. These discrepancies occur because sound intensity drops according to the inverse square law, as will be appreciated. However, traditional AGC techniques are not designed to account for such discrepancies up front because they are agnostic with respect to lobe positions or distances from the talker to the microphone. Thus, it may take the AGC several seconds to scan through past samples and determine that a gain adjustment is needed to boost the signal level of the far away talker to match that of the closer talker. During this delay, speech from the far away talker may sound choppy or unintelligible to the far end listeners. Moreover, in some cases, the AGC may have a limited range of available gain adjustments which prevents the AGC from adequately boosting the incoming signal level. Thus, there is still a need for an audio system that can provide high quality audio and a consistent listening experience for far end listeners.

The systems and methods described herein can improve the configuration and usage of audio systems, such as, e.g., conferencing systems and other array microphone systems, by using sound location information (e.g., localization coordinates) to calculate a direct distance between a microphone and an audio source detected by the microphone, and based on that distance, identify an appropriate gain adjustment for a microphone lobe directed towards the detected audio source. In addition, an accuracy of the direct distance calculation can be improved by using height information, such as a height of the microphone and/or a height of the audio source (or talker), to normalize the radius estimation of the sound location information, which tends to be less precise that the elevation and azimuth angle estimations. The improved distance calculation enables faster identification of the lobe gain adjustment needed to provide a uniform signal level across all input channels of the array microphone. Moreover, the gain value for each channel may be optimized by using an appropriate gain parameter selected based on the improved distance calculation and height information. Thus, the techniques described herein can be used to provide automatic, accurate, and immediate (e.g., within one second) lobe gain adjustment for array microphones.

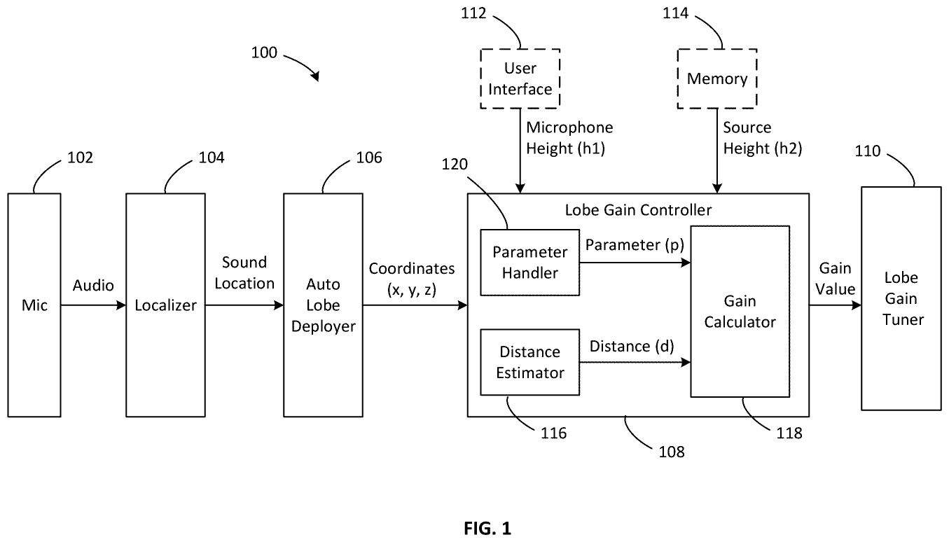

FIG. 1 depicts an exemplary audio system 100 that may be used to automatically adjust lobe gain based on detected talker distance information, or otherwise implement one or more of the techniques described herein, in accordance with embodiments. As shown, the audio system 100 comprises a microphone 102, an audio localizer 104, an automatic lobe deployer 106, a lobe gain controller 108, and a lobe gain tuner 110. These components of the audio system 100 may be in wired and/or wireless communication with each other and/or other components of the system 100, and may be implemented in hardware, software, or a combination thereof. Though shown as standalone components in FIG. 1, in some embodiments all components of the audio system 100 may be included in the same device (e.g., an array microphone system). In other embodiments, the audio system 100 may include a first device (e.g., array microphone) in communication with a second device (e.g., a computing device, signal processor, controller, etc.). For example, the first device may include the microphone 102, the audio localizer 104, and/or the automatic lobe deployer 106, and the second device may include the lobe gain controller 108 and/or the lobe gain tuner 110. For brevity and clarity reasons, this disclosure describes the microphone 102 as being integrated with at least the audio localizer 104 and the automatic lobe deployer 106, though other configurations are contemplated and possible.

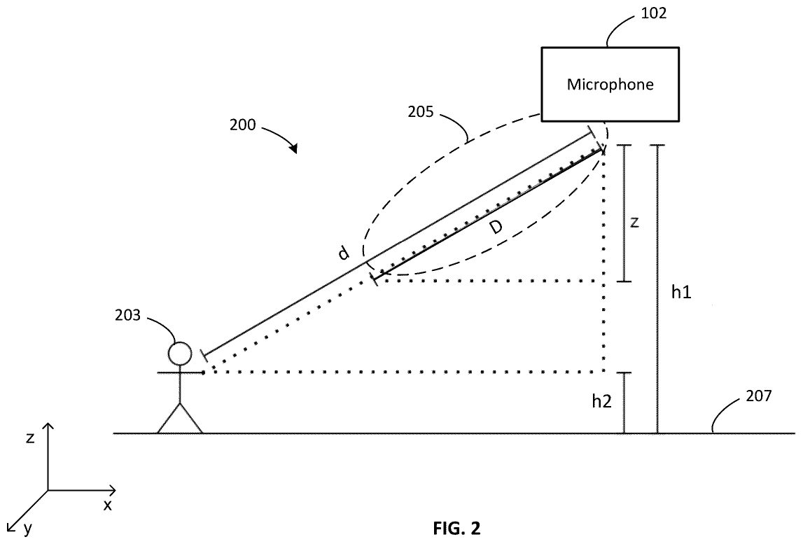

Referring additionally to FIG. 2, shown is an exemplary environment 200 in which the audio system 100 may be used, in accordance with embodiments. As shown, the environment 200 includes the microphone 102 and an audio source 203 located a distance, d, from the microphone 102. The environment 200 may be a conference room, a boardroom, a classroom, or other meeting room; a theater, sports arena, auditorium, or other performance or event venue; or any other space. The audio source 203 may be a human speaker, or talker, located in the environment 200 (e.g., near end) and participating in a conference call, telecast, webcast, class, seminar, performance, sporting event, or any other event, with one or more other participants, or listeners, located in a second environment or space (e.g., far end).

According to embodiments, the microphone 102 can be configured to detect an active talker located in the environment 200, such as the audio source 203, and determine sound location information for the active talker, for example, using the audio localizer 104 shown in FIG. 1. Based on the sound location information, the microphone 102 can determine a set of coordinates (or “localization coordinates”) that represent an estimated location of the audio source 203 and, as shown in FIG. 2, can use the localization coordinates to direct an audio pickup lobe 205 towards the audio source 203, for example, using the automatic lobe deployer 106 of FIG. 1.

In general, the microphone 102 can be configured to detect sounds from the audio source 203 such as human voice or speech spoken by the audio source 203 and/or music, clapping, or other sounds generated by the same, and convert the detected sounds into an audio signal. Though only one microphone 102 is shown in FIGS. 1 and 2, the microphone 102 can include one or more of an array microphone, a non-array microphone (e.g., directional microphones such as lavalier, boundary, etc.), or any other type of audio input device capable of capturing speech and other sounds. As an example, the microphone 102 may include, but is not limited to, SHURE MXA310, MX690, MXA910, MXA920, MXW1/2/8, ULX-D, and the like.

The microphone 102 may be placed in any suitable location, including on a wall, ceiling, table, lectern, and/or any other surface in the environment 200, and may conform to a variety of sizes, form factors, mounting options, and wiring options to suit the needs of the particular environment. The microphone 102 may be positioned at a select location in the environment 200 in order to adequately capture sounds throughout the environment 200. For example, the microphone 102 may be mounted overhead, as shown in FIG. 2, or on a wall in order to capture the sound from a larger area, e.g., an entire room or hall. In other cases, one or more microphones may be placed on a table, lectern, or other surface near the audio sources in a classroom or conference room environment, or may be attached to the audio sources, e.g., a performer or speaker, in an auditorium, stadium, or musical hall environment. The exact type, number, and placement of microphone(s) in a particular environment may depend on the locations of audio sources, listeners, physical space requirements, aesthetics, room layout, stage layout, and/or other considerations.

In the illustrated embodiment, the microphone 102 is attached to, or mounted on, a ceiling or other top surface of the environment 200 in order to capture sounds produced throughput the environment 200. The microphone 102 may be integrated into the ceiling, or a ceiling tile included therein, coupled to a post (not shown) that is attached to the ceiling, suspended from the ceiling using one or more wires or cables, or otherwise attached to the ceiling, as will be appreciated. Regardless of the exact mounting method, the microphone 102 may be situated at a defined distance from a floor 207 of the environment 200, i.e. height, h1, shown in FIG. 2.

In embodiments, the microphone 102 can be configured to form one or more pickup patterns with lobes that can be steered to sense audio in particular locations within the environment 200. For example, the microphone 102 may be an array microphone comprised of a plurality of microphone elements (not shown), each of which is configured to detect sound and convert the detected sound to a digital or analog audio signal. In such cases, audio output signals generated by the microphone 102 may be configured to correspond to one or more pickup patterns, which may be composed of, or include, one or more lobes (e.g., main, side, and back lobes) and/or one or more nulls. The pickup patterns formed by the microphone 102 may be dependent on the type of beamformer used with the microphone elements. For example, a delay and sum beamformer may form a frequency-dependent pickup pattern based on its filter structure and the layout geometry of the microphone elements. As another example, a differential beamformer may form a cardioid, subcardioid, supercardioid, hypercardioid, or bidirectional pickup pattern. Other suitable types of beamformers may include a minimum variance distortionless response (“MVDR”) beamformer, and more. Though not shown, the microphone 102 may comprise one or more beamformers configured to generate the desired audio pick-up patterns, or microphone lobes.

It should be understood that the components shown in FIG. 2 are merely exemplary, and that any number, type, and placement of the various components in the environment 200 are contemplated and possible, including, for example, different arrangements of the audio source 203, an audio source that moves about the room, different locations for the microphone 102, a different number of audio sources 203 and/or microphones 102, etc. For example, though not shown, the environment 200 may include a plurality of audio sources located throughout the environment 200, such audio sources including the talker 203 and one or more other persons and/or objects that produce sound (e.g., loudspeakers, musical instruments, phones, tablets, computers, HVAC equipment, etc.). In such cases, the microphone 102 may be configured to detect each of the audio sources (e.g., using various microphone lobes) and/or the environment 200 may include two or more microphones 102 distributed throughout the environment 200 in order to capture the plurality of audio sources.

Referring again to FIG. 1, though not shown, the audio system 100 may be configured for multi-channel audio, as will be appreciated. For example, the audio signals detected by the microphone elements of the microphone 102 may be received as inputs to respective channels of the microphone 102. The input audio signals may be provided to a beamformer of the microphone 102, which has a plurality of output channels that respectively correspond to the individual microphone lobes formed by the beamformer. The beamformed audio channels of the microphone 102 may be configured to provide the audio signal captured by the corresponding lobe to a corresponding input channel of the audio localizer 104, which outputs sound location information for that lobe to the automatic lobe deployer 106 using a corresponding output channel. In some embodiments, the automatic lobe deployer 106 may be configured to use a corresponding channel to provide localization coordinates for a new or reset lobe to the lobe gain controller 108. In various embodiments, the audio system 100 may include a digital signal processor (“DSP”), or processing component, that has a plurality of audio channels for respectively receiving a plurality of audio signals captured by the microphone 102, the digital signal processor comprising the audio localizer 104, the automatic lobe deployer 106, the lobe gain controller 108, the lobe gain tuner 110, or any combination thereof.

As shown in FIG. 1, the microphone 102 can be configured to provide audio signals captured from an active audio source detected by the microphone 102 to the audio localizer 104 (also referred to as an “audio activity localizer”). The audio localizer 104 can be configured to generate or provide sound location information for the detected audio source (e.g., talker 203 of FIG. 2) using an audio localization algorithm. The sound location information can include an audio localization or other data that indicates an estimated location of the sound, or audio activity, detected by the microphone 102 (e.g., speech generated by talker 203). For example, the audio localizer 104 can be configured to determine a direction of arrival of the audio activity relative to the microphone 102 and based thereon, generate a localization of the detected audio, or an estimated location of the audio relative to the microphone 102. In various embodiments, the audio localization, and thus the sound location information, can include a set of coordinates (or “localization coordinates”) that represents the estimated location of the detected audio activity relative to the microphone 102 (also referred to as “estimated talker location”).

The audio localizer 104 may use any of the various methods for generating sound localizations that are known in the art, including, for example, a Generalized Cross Correlation Phase Transform (GCC-PHAT) algorithm or other GCC algorithm, a Steered-Response Power Phase Transform (SRP-PHAT) algorithm, a time of arrival (TOA)-based algorithm, a time difference of arrival (TDOA)-based algorithm, Multiple Signal Classification (MUSIC) algorithm, an artificial intelligence-based algorithm, a machine learning-based algorithm, and others. As will be appreciated, the location obtained by any sound source localization algorithm may represent a perceived location of the audio activity or other estimate obtained based on the audio signals received from the microphone 102, which may or may not coincide with the actual or true location of the audio activity.

The localization coordinates output by the audio localizer 104 may be Cartesian or rectangular coordinates that represent a location point in three dimensions, i.e. x, y, and z values, or polar or spherical coordinates, i.e. azimuth (phi), elevation (theta), and radius (r). In some cases, the localization coordinates may be transformed from one format to the other, for example, using a transformation formula, as is known in the art, by the audio localizer 104 or other component of the audio system 100, as needed. The spherical coordinates may be used in various embodiments to determine additional information about the environment 200, such as, for example, a direct distance between the active talker 203 and the microphone 102. In some embodiments, the localization coordinates for the detected sound position may be relative to a coordinate system of the microphone 102 and may be converted or translated to a coordinate system of the environment 200, or vice versa. In various embodiments, the sound location information generated by the audio localizer 104 also includes a timestamp or other timing information to indicate the time at which the coordinates were generated, an order in which the coordinates were generated, and/or any other information to help identify coordinates that were generated simultaneously, or nearly simultaneously, for the same audio source 203.

In some embodiments, the audio localizer 104 can be configured to use a clustering algorithm to improve an accuracy of the estimated talker location by preventing outliers and other erroneous localizations from being used for determination of the estimated talker location. For example, the clustering algorithm can cluster together a plurality of audio localization coordinates (or points) obtained over time by the microphone 102 for the same or similar area (e.g., around the audio source 203) and identify, based on proximity for example, which set of coordinates within the cluster is most likely to represent the actual location of the audio source 203. The audio localizer 104 may then use the identified set of coordinates to represent the estimated talker location for the audio source 203. Other techniques may also be used to improve a general accuracy of the sound location information used to generate the estimated talker location, as will be appreciated.

While the above examples describe the use of audio localizations to identify an estimated talker location, in other embodiments, the microphone 102 and/or the audio localizer 104 may use other types of information to identify a talker location, in addition to, or instead of, the audio source localization coordinates. For example, the audio system 100 may further include one or more other sensors (i.e. besides the microphone 102) that are configured to detect or determine a current location of a human talker or other audio source within a designated audio coverage area. Such additional sensors may include a thermal sensor, an infrared sensor or other optical sensor, an ultrasonic sensor, a Time-of-Flight (“ToF”) sensor, a video camera or other imagery-based sensor, a millimeter-wave (“mmWave”) sensor or other human presence detection sensor, and/or any other suitable sensor or device. Accordingly, the sound location information may include audio localization coordinates determined by the microphone 102 for estimating the talker location and/or other types of talker location information determined by other types of sensor(s).

As shown in FIG. 1, the audio localizer 104 provides the sound location information, which may include the localization coordinates and/or other data indicating the estimated talker location, to the automatic lobe deployer 106. In general, the automatic lobe deployer 106 can be configured to use the sound location information to automatically place or deploy a beamformed microphone lobe (also referred to as “audio pick-up lobe”) in the direction of a talker or other audio activity detected by the microphone. For example, in FIG. 2, based on localization coordinates (x, y, z), the automatic lobe deployer 106 may direct an audio pick-up lobe 205 towards the audio source 203 for capturing the sounds produced thereby.

In embodiments, the automatic lobe deployer 106 can be configured to select and perform one of a plurality of actions depending on the estimated talker location. For example, in some cases, based on receiving localization coordinates or other indication of an estimated talker location, the automatic lobe deployer 106 may determine that a new microphone lobe is needed to cover newly detected audio activity because any existing lobes are not able to adequately reach or cover the estimated talker location. In some cases, the automatic lobe deployer 106 may decide to reset an existing microphone lobe by re-directing the existing lobe to an original lobe location, for example, based on determining that a previously detected audio source has moved back to its original talker location (e.g., after moving about the environment 200) and/or the current lobe location no longer covers the original talker location. In other cases, the automatic lobe deployer 106 may decide to reposition an existing microphone lobe, for example, by shifting its current position to a new position that covers the newly detected audio activity, using an automatic focus feature or the like.

Once the selected action is performed, the automatic lobe deployer 106 may provide a set of coordinates associated with the microphone lobe 205 to the lobe gain controller 108 for use in applying a gain adjustment to the corresponding beamforming channel, as needed (e.g., if the talker 203 is talking louder than other near end participants, etc.). In some cases, the coordinates received at the lobe gain controller 108 from the automatic lobe deployer 106 may be the localization coordinates determined by the audio localizer 104 for the estimated location of the detected talker 203. In some cases, the received coordinates may indicate or represent a location of the microphone lobe 205, or the location at which the lobe was placed, which may or may not coincide with the estimated talker location. While FIG. 2 shows the coordinates as Cartesian coordinates, e.g., (x, y, z), it should be appreciated that the coordinates received at the lobe gain controller 108 may be spherical coordinates instead. For example, the lobe gain controller 108 may be configured to transform the spherical coordinates to Cartesian coordinates, or vice versa.

In various embodiments, the lobe gain controller 108 can be configured to adjust the gain on a corresponding beamforming channel only when a new lobe is deployed, or an existing lobe is reset to its original position. In some cases, the automatic lobe deployer 106 may be configured to provide the set of coordinates to the lobe gain controller 108 in response to, or based on, deployment of a new lobe or resetting an existing lobe. In all other scenarios, including, for example, when an existing lobe is automatically focused or repositioned, the lobe coordinates may not be provided to the lobe gain controller 108. In other cases, the automatic lobe deployer 106 may be configured to provide the set of coordinates to the lobe gain controller 108 regardless of the selected lobe action, and the lobe gain controller 108 may be configured to determine whether to perform a lobe gain adjustment based on the action (i.e. deployment of a new lobe, resetting an existing lobe, or repositioning an existing lobe) selected by the automatic lobe deployer 106 for those coordinates.

In general, existing localization algorithms that are based only on audio signals offer relatively precise estimates for elevation and azimuth coordinates, but less accurate estimates for the radius coordinate. This can be due to various factors, such as, for example, a small microphone aperture size, an overall geometry of the microphone array, and/or a sampling rate of the audio signals. The inaccuracy of the radius coordinate can lead to an inaccurate estimation of talker distance, D, or the direct distance between a microphone and a detected talker, as shown in FIG. 2. As will be appreciated, when based off xyz localization coordinates, an estimate of the direct distance D may be calculated using Equation 1:

$$D = \sqrt{{x}^{2} + {y}^{2} + {z}^{2}} . \qquad ( 1 )$$

As shown in FIG. 2, for example, the talker distance estimation D obtained using Equation 1 falls significantly short of the actual location of the talker 203.

According to embodiments, the lobe gain controller 108 can be configured to improve an accuracy of the talker distance estimation by mitigating inaccuracies in the direct distance calculation due to radius estimation errors. In particular, the lobe gain controller 108 can be configured to use the z coordinate and height information associated with the environment 200 to normalize the radius estimation, or otherwise calculate a height-corrected estimation of the talker distance.

In various embodiments, the lobe gain controller 108 may be configured to receive the height information from a user interface 112 (e.g., keyboard, touchscreen, microphone, or other user input device) and/or retrieve the height information from a memory 114 of the audio system 100, as shown in FIG. 1. In some embodiments, the user interface 112 and/or the memory 114 may be included in, or integrated with, the lobe gain controller 108. In other cases, the user interface 112 and/or the memory 114 may be included in, or integrated with, the microphone 102 or other component of the audio system 100. In some cases, the height information may be stored in a database or other memory associated with the environment 200 and in communication with the audio system 100 and/or the lobe gain controller 108.

The height information may comprise the height, h1, of the microphone 102 relative to the floor 207 or any other height or distance measurement associated with the microphone 102 (also referred to herein as “microphone height” or “first height”). The first height h1 may be provided by an installer or other user of the audio system 100, for example, during set up of the microphone 102 and/or the audio system 100. For example, after installing the microphone 102 within the environment 200, the installer may measure a distance from the floor 207 to the microphone 102 and input that distance measurement as the microphone height h1, using the user interface 112. Such height measurement may be needed when the microphone 102 is suspended from the ceiling by wires, cables, one or more poles, etc., or otherwise coupled to the ceiling and configured to extend a certain distance below the ceiling, for example. In other cases, the height measurement may be or include a ceiling height for the environment 200, or the distance between the ceiling and the floor 207, for example, when the microphone 102 is mounted to, or integrated into, the ceiling, such that the microphone 102 is substantially flush with the ceiling. In some cases, the microphone height h1 may be previously known and stored in the memory 114, and thus available for retrieval by the lobe gain controller 108.

The height information may also comprise a height, h2, of the audio source 203 or any other height measurement associated with the audio source 203 (also referred to herein as “source height” or “second height”). The second height h2 may be previously stored in the memory 114 and available for retrieval by the lobe gain controller 108, as shown in FIG. 1. In some cases, the second height h2 may be a preset parameter or value included in, or associated with, a gain adjustment algorithm used by the lobe gain controller 108. In other cases, the second height h2 may be entered by the installer or other user using the user interface 112, for example, at the time of installation or setup of the microphone 102 and/or the lobe gain controller 108, and then stored in the memory 114. According to some embodiments, the second height h2 may be the typical height for a talker in the environment 200 (e.g., 1.5 m, 1.75 m, 2 m, etc.), or the height of an average-sized person. In some cases, the second height h2 may be determined based on historical data for the environment 200, such as, e.g., an average height of the talkers detected in the environment 200 over a select time period. In such cases, the height of each talker may be calculated, by a processor of the lobe gain controller 108 and/or the audio system 100, for example, based on the localization coordinates or other sound location information obtained for the audio source 203.

As shown in FIG. 1, the lobe gain controller 108 comprises a distance estimator 116 configured to use the received height information to calculate a more accurate distance measurement, d, between the microphone 102 and the audio source 203, to be used for the automatic lobe gain adjustment. For example, as shown in FIG. 2, the distance estimator 116 can be configured to calculate the improved distance measurement d by using a distance estimation technique that modifies Equation 1 based on the similar triangles theorem and uses the height information to correct or normalize the radius estimation determined by the audio localizer 104, as shown by Equation 2:

$$d = \sqrt{{x}^{2} + {y}^{2} + {z}^{2}} * ( h 1 - h 2 ) / z . \qquad ( 2 )$$

That is, the distance estimation technique calculates a height-corrected estimation of the direct distance between the microphone 102 and the talker 203 by scaling the traditional direct distance estimation D by a height differential ratio, or the ratio of an estimated height coordinate, derived from known height information (i.e., (h1-h2)), and the z coordinate, which is derived from the sound location information provided by the audio localizer 104.

As shown in FIG. 1, the lobe gain controller 108 further comprises a gain calculator 118 configured to receive the improved distance estimation d from the distance estimator 116 and based on that distance, determine a gain value, e.g., in decibels (dB)), for the audio pickup lobe 205 (or corresponding channel) directed towards the detected audio source 203 by the microphone 102. The gain calculator 118 can be further configured to determine an optimal gain value for the audio pick-up lobe 205 by mapping the distance estimation d to an appropriate gain parameter p received from a parameter handler 120. As shown in FIG. 1, the parameter handler 120 may be included in the lobe gain controller 108 as well. In other embodiments, the parameter handler 120 may be a standalone component (e.g., a digital signal processor, etc.) or located in another component of the audio system 100 (e.g., the memory 114), and may be in communication with the lobe gain controller 108 and/or the gain calculator 118.

According to embodiments, the parameter handler 120 can be configured to determine a plurality of gain parameters based on a set of predefined rules, or conditions, designed to identify the optimal gain value for various talker distances. In particular, the parameter handler 120 may be configured to use the predefined rules to establish appropriate default and threshold values (or “threshold information”) based on the specific characteristics of the environment 200, such as, for example, a height of the room or environment, a size of the applicable audio coverage area, the microphone height h1, the source height h2, etc. The parameter handler 120 may be further configured to define or determine each of the plurality of gain parameters based on the threshold information. For example, the plurality of gain parameters may include a minimum parameter for setting the gain value to a minimum value (or a default gain value) if the talker distance is equal to or less than a lower threshold, a maximum parameter for setting the gain value to a maximum value (or a constant gain value) if the talker distance is equal to or greater than an upper threshold, and a medium parameter for using a ratio to set the gain value if the talker distance is between the lower threshold and the upper threshold.

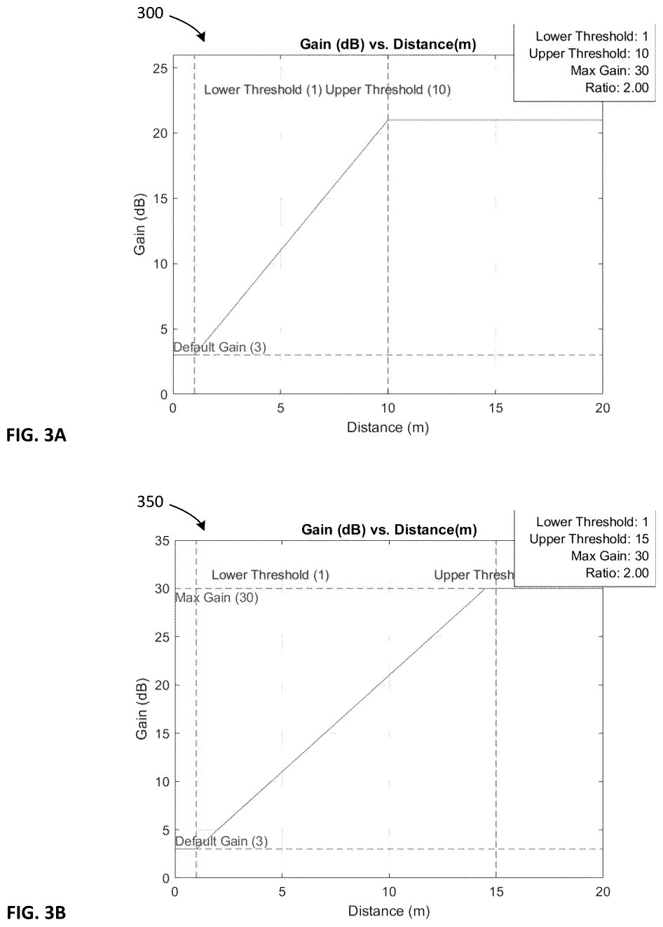

In various embodiments, the parameter handler 120 may be configured to determine or calculate the lower threshold based on the microphone height h1 and the source height h2. For example, the lower threshold may be calculated by subtracting the source height from the microphone height, or h1-h2. In addition, the parameter handler 120 may be configured to determine or calculate the upper threshold based on the microphone height h1, a size of the audio coverage area within which the audio source 203 is located, and/or other measurement that ensures that the distance value used for gain computation does not exceed the size of the environment 200 (or room), the applicable coverage area, or the boundary between free field and reverberant field within the environment 200 (e.g., in the context of sound propagation). For example, the upper threshold may be set equal to, or based on, a distance from the microphone 102 to a furthest wall in the environment 200. The parameter handler 120 may be further configured to determine the ratio that is used for the medium parameter by calculating the rate at which the gain increases between the lower threshold and the upper threshold. For example, FIGS. 3A and 3B illustrate two exemplary scenarios in which the ratio is two decibels per meter (dB/m).

As shown in FIG. 1, the parameter handler 120 can be further configured to provide parameter information, including the plurality of gain parameters and the threshold information, to the gain calculator 118. Based on the received parameter information, and the distance d received from the distance estimator 116, the gain calculator 118 can select one of the plurality of gain parameters (e.g., parameter p) as being most appropriate for determining an optimal gain value for the estimated talker location. For example, the gain calculator 118 may be configured to select the minimum parameter if the distance estimation d is equal to or less than the lower threshold, select the maximum parameter if the distance estimation d is equal to or greater than the upper threshold, and select the medium parameter if the distance estimation d is between the lower threshold and the upper threshold.

The gain calculator 118 can be further configured to calculate or determine a gain value for the corresponding lobe (or channel) based on the selected gain parameter p. For example, if the minimum parameter is selected, the gain calculator 118 may set the gain value to the default gain value. If the maximum parameter is selected, the gain calculator 118 may set the gain value to the maximum value. And if the medium parameter is selected, the gain calculator 118 may calculate the gain value by multiplying the distance estimation d by the ratio.

As shown in FIG. 1, the gain value determined by the gain calculator 118 can be output by the lobe gain controller 108 to the lobe gain tuner 110, which may be configured to apply the gain value to the appropriate lobe (or channel). In some cases, the lobe gain tuner 110 may be part of, or comprised in, an automatic gain controller (or AGC, not shown) of the audio system 100. In such cases, the lobe gain controller 108 may be used to improve gain adjustments made by the AGC to provide a relatively consistent signal level across all lobes or channels. In other cases, the lobe gain tuner 110 may operate independently of the AGC. For example, the lobe gain tuner 110 may be configured to adjust the lobe gain before the signal is provided to the AGC for further processing. In such cases, the lobe gain tuner 110 can bring the signal level to a more adequate level a priori, based on the gain value determined by lobe gain controller 108, and the AGC can further process the adjusted signal level, as needed, using the full range of gain adjustments that are available to it. In this manner, the improved gain adjustment techniques of the lobe gain controller 108 can also help improve AGC performance.

In some embodiments, the lobe gain controller 108 may be a standalone device, such as a control module, control device, computing device, or other electronic device, or included in such a device. In other embodiments, all or portions of the lobe gain controller 108 may be included in the microphone 102 and/or integrated with one or more of the audio localizer 104, the automatic lobe deployer 106, and/or the lobe gain tuner 110. In one exemplary embodiment, the lobe gain controller 108 may be a generic computing device comprising a processor and a memory device. In another exemplary embodiments, the lobe gain controller 108 may be part of a cloud based system or otherwise reside in an external network.

It should be understood that the components shown in FIG. 1 are merely exemplary, and that any number, type, and placement of the various components in the audio system 100 are contemplated and possible, including, for example, a different number of microphones 102 and/or the addition of components not shown here (e.g., a beamformer, voice activity detector, automatic lobe focuser, an equalizer, etc.). In various embodiments, one or more components of the audio system 100 may include one or more digital signal processors or other processing components, controllers, wireless receivers, wireless transceivers, and other units not shown. Moreover, while specific equations and algorithms are described herein, other, similar techniques may also be used, in addition to or in the alternative, to improve the coordinates estimated for a detected talker.

According to various embodiments, the audio system 100 can be scaled up to a multi-device conferencing system, or eco-system, for example, by providing a plurality of microphones (not shown) in the same environment (e.g., environment 200 of FIG. 2) and by connecting the components of the audio system 100, including the multiple microphones and a central aggregator or other processor, to each other using a common communication network. In such cases, the microphones may be configured to share the direct distance estimations calculated for each detected audio source with the aggregator, and the aggregator may be configured to use the multiple estimations to optimize gain computations across all of the channels in the environment that picks up the audio source. In this manner, the audio system can be configured to prevent or minimize sudden volume drops in the audio signal sent to far-end participants and thus, improve the far-end audio quality across the eco-system. In some embodiments, the radius coordinate of the estimated talker location may be further improved or corrected by using, in addition to the height information, localization information from multiple microphones in the environment 200 and/or sensor data obtained by one or more sensors (e.g., video camera/sensor, ultrasonic sensor, millimeter wave sensor, infrared sensor, etc.) included in the audio system 100, as described herein.

Referring now to FIG. 3A, shown is a first graph 300 plotting exemplary parameter information that may be used by the audio system 100, or more specifically, the lobe gain controller 108, to automatically adjust a lobe gain applied to the channel that corresponds to the audio source 203, in accordance with embodiments. As shown, the first graph 300 plots gain, in decibels (dB), versus distance, in meters (m), for a given environment (e.g., the environment 200 of FIG. 2). More specifically, the first graph 300 plots the minimum and maximum gain values set for the given environment, as well as the upper and lower thresholds calculated for the distance value based on height information (e.g., microphone height h1, source height h2, etc.) and/or other environmental information (e.g., coverage area size, etc.), as described herein. The first graph 300 also plots the ratio used for the medium parameter by drawing a line between the lower threshold and the upper threshold to represent the rate at which the gain increases between the two thresholds. In the illustrated embodiment, the lower threshold is 1 m, the upper threshold is 10 m, the maximum gain is 30 dB, the default or minimum gain is 3 dB, and thus, the ratio is 2 dB/m. As another example, FIG. 3B shows a second graph 350 plotting a different set of parameter information. In this second embodiment, the lower threshold is 1 m, the upper threshold is 15 m, the maximum gain is 30 dB, the default or minimum gain is 3 dB, and thus, the ratio is still 2 dB/m. In other embodiments, other rates or values for the ratio are possible and contemplated.

In some embodiments, the lobe gain controller 108 may be configured to receive sound location information from one or more components of the audio system 100 that are located in another room or environment over an Internet Protocol (IP) such as, e.g., TCP port 2202 or the like. For example, the audio system 100 may include a plurality of microphones 102 located in the same space and/or a nearby space (not shown). In some cases, each of the plurality of microphones 102 may be in communication with the lobe gain controller 108 in order to provide respective localization coordinates and height information to the lobe gain controller 108 and receive adjusted gain values for the lobes of that microphone 102, as needed. In other cases, the audio system 100 may include a plurality of lobe gain controllers 108 in communication with respective microphones 102 (i.e. one controller 108 for each microphone 102) or multiple microphones 102 (e.g., two microphones 102 per controller 108), depending on the locations of the microphones 102 and/or the controllers 108, processing and/or channel limitations at each controller 108, and other relevant concerns.

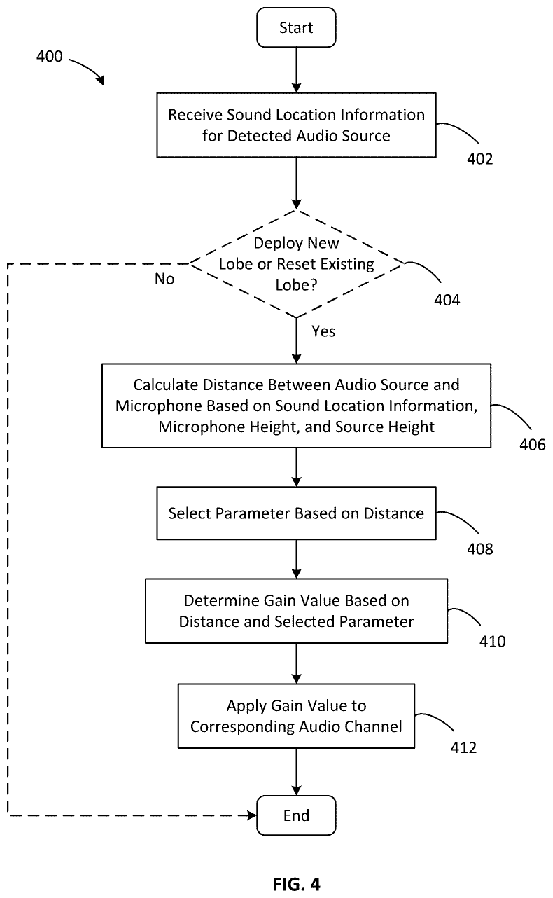

FIG. 4 illustrates an exemplary method or process 400 for automatically adjusting lobe gain based on sound location information obtained using at least one microphone, in accordance with embodiments. The at least one microphone (e.g., microphone 102 of FIG. 1) may form part of an audio system (e.g., system 100 of FIG.) located in an environment (e.g., environment 200 of FIG. 2). The environment may be a conferencing room, event space, or other area that includes one or more talkers (e.g., talker 203 of FIG. 2) or other audio sources. The at least one microphone may be configured to detect and capture sounds produced by the talker(s) and determine the locations of the detected sounds. The method 400 may be performed by one or more processors of the audio system that are in communication with the at least one microphone, such as a processor of a computing device included in the system and communicatively coupled to the at least one microphone. In some cases, the method 400 may be performed by a control module or controller (e.g., lobe gain controller 108 of FIG. 1) included in the audio system or otherwise in communication with the at least one microphone.

As shown in FIG. 4, the method 400 may include, at step 402, receiving, from the at least one microphone, sound location information for an audio source detected by the at least one microphone. For example, the sound location information may be audio localizations obtained by the microphone 102 based on audio detected for the audio source 203. In some embodiments, the method 400 further comprises determining the sound location information using an audio localization algorithm executed by an audio activity localizer (e.g., audio localizer 104 of FIG. 1) included in, or in communication with, the at least one microphone, for example, using the localization techniques described herein. In some embodiments, the method 400 also comprises determining, based on the sound location information, a set of coordinates representing an estimated location of the audio source, for example, using the audio activity localizer; and using the set of coordinates to direct the audio pickup lobe towards the audio source, for example, using an automatic lobe deployer (e.g., automatic lobe deployer 106 of FIG. 1). The set of coordinates (or “localization coordinates”) may be in Cartesian or spherical form, as will be appreciated.

In various embodiments, the method 400 may be configured to apply a lobe gain adjustment only when the automatic lobe deployer deploys a new audio pick up lobe (or microphone lobe) or resets an existing audio pick up lobe to its original position. In such cases, the method 400 may include, at step 404, determining whether a new microphone lobe has been deployed towards the detected audio source, or an existing microphone lobe has been reset to cover the audio source. In some embodiments, step 404 may further include selecting, based on the sound location information received from the at least one microphone, and using, for example, the automatic lobe deployer, one of the following actions: deployment of a new audio pickup lobe, resetting of an existing audio pickup lobe, or repositioning of an existing audio pickup lobe. Step 404 may also include, based on selecting of the deployment or resetting actions, or a “yes” determination, proceeding with calculating the distance at step 406. If, on the other hand, the answer at step 404 is “no,” i.e. based on selecting of the repositioning action, the method 400 may end, as no lobe gain adjustment is needed, or may go back to start (not shown) and wait for new sound location information. In other embodiments, the method 400 may be configured to apply a lobe gain adjustment in all scenarios, including repositioning of an existing lobe (e.g., using an automatic focus feature, etc.), and thus, may not include step 404.

Step 406 includes calculating a distance between the audio source and the at least one microphone based on the sound location information, a first height associated with the at least one microphone, and a second height associated with the audio source. In embodiments, this distance, such as distance d shown in FIG. 2, may be calculated or estimated using a height-corrected formula that uses environmental height information (i.e. the first height and the second height) to mitigate inaccuracies in the direct distance estimation (e.g., distance D shown in FIG. 2), traditionally calculated using Equation 1 provided herein, due to errors in the radius estimation included in, or derived from, the received sound location information. For example, a height-corrected estimation of the direct distance between the audio source and the at least one microphone may be calculated using Equation 2 provided herein, which normalizes the otherwise inaccurate radius estimation. The distance calculation at step 406 may be performed by a control module, controller, or other processor of the audio system (e.g., lobe gain controller 108 and/or distance estimator 116 of FIG. 1). The first height may be a height of the at least one microphone relative to a floor of the environment, such as microphone height h1 shown in FIG. 2, and may be entered by a user or installer of the audio system via a user interface (e.g., user interface 112 of FIG. 1). The second height, such as source height h2 shown in FIG. 2, may be an actual height of the detected audio source or an average talker height previously stored in a memory of the audio system (e.g., memory 114 of FIG. 1), for example.

In various embodiments, the method 400 further includes, at step 408, selecting one of a plurality of gain parameters based on the distance calculated at step 406. The gain parameters may be configured to help calculate an optimal gain value for the audio pickup lobe depending on the estimated distance between the detected audio source and the at least one microphone. For example, the plurality of gain parameters may comprise a minimum parameter for setting the gain value to a minimum value, a maximum parameter for setting the gain value to a maximum value, and a medium parameter for using a ratio to set the gain value. In such cases, selecting one of the plurality of gain parameters at step 408 may comprise selecting the minimum parameter if the distance is equal to or less than a lower threshold, selecting the maximum parameter if the distance is equal to or greater than an upper threshold, and selecting the medium parameter if the distance is between the lower threshold and the upper threshold, as described herein. In some embodiments, the method 400 further comprises determining the lower threshold based on the first height and the second height, and/or determining the upper threshold based on the first height. The ratio may be a rate at which the gain increases between the lower threshold and the upper threshold (e.g., as shown in FIGS. 3A and 3B). The plurality of gain parameters, the related threshold information, and all other parameter information may be calculated and/or provided by a parameter handler (e.g., parameter handler 120 of FIG. 1) included in, or in communication with, the lobe gain controller. The parameter selection at step 408 may be performed by a gain calculator (e.g., gain calculator 118 of FIG. 1) in communication with the parameter handler and also included in, or in communication with, the lobe gain controller.

Step 410 includes determining, based on the distance, a gain value for an audio pickup lobe directed towards the audio source by the at least one microphone. In embodiments where an appropriate gain parameter is selected at step 408, step 410 further includes calculating the gain value based on the selected gain parameter, such as parameter p of FIG. 2, and the distance d calculated at step 406. For example, if the minimum parameter is selected at step 408, the gain value determined at step 410 may be the minimum gain value, or default gain value (e.g., 3 dB as shown in FIGS. 3A and 3B). As another example, if the maximum parameter is selected at step 408, the gain value determined at step 410 may be the maximum gain value (e.g., 30 dB as shown in FIGS. 3A and 3B). And if the medium parameter is selected at step 408, the gain value determined at step 410 may be equal to the estimated talker distance d multiplied by the ratio (e.g., 2 dB as shown in FIGS. 3A and 3B). The gain value may be calculated or determined by a gain calculator (e.g., gain calculator 118 of FIG. 1) included in, or in communication with, the lobe gain controller. The gain calculator also may be in communication with the parameter handler for receiving the parameter information, and the distance estimator for receiving the calculated distance.

At step 412, the method 400 includes applying the gain value to an audio channel of the at least one microphone, the audio channel configured to receive audio signals captured using the audio pickup lobe directed towards the detected audio source. For example, a gain amount applied to the audio channel, and/or an amplitude of the audio signal received at the audio channel, may be increased or decreased as needed to substantially match the gain value determined at step 410. The gain value may be applied to the audio pick up lobe (e.g., lobe 205 of FIG. 2) using a lobe gain tuner (e.g., lobe gain tuner 110 of FIG. 1) that is in communication with the lobe gain controller for receiving the gain value determined at step 410. The method 400 may end once step 412 is complete.

Thus, the techniques described herein can be used to provide automatic, accurate, and immediate (e.g., within one second) lobe gain adjustment for array microphones and the like by utilizing an automated height-corrected technique that (1) uses environmental height information to correct errors in the radius estimation for a detected audio source and thereby, improve an accuracy of the direct distance calculated between the audio source and the microphone that detected it, and (2) based on the improved direct distance calculation, optimizes the gain adjustment applied to an audio pickup lobe directed towards the detected audio source. In particular, the environmental height information, such a height of the microphone relative to the floor of an environment and a height of the audio source, on average, may be used to normalize the radius estimation included in the sound location information obtained for the detected audio source and thus, mitigate inaccuracies in the direct distance calculation. The height information can also be used to quickly map the improved direct distance estimation to an optimal gain value for the corresponding lobe using predefined rules and parameters and thus, boost the audio source's volume with minimal or no perceivable delay (e.g., less than 1 second).

The components of the audio system 100 may be implemented in hardware (e.g., discrete logic circuits, application specific integrated circuits (ASIC), programmable gate arrays (PGA), field programmable gate arrays (FPGA), digital signal processors (DSP), microprocessor, etc.), using software executable by one or more computers, such as a computing device having a processor and memory (e.g., a personal computer (PC), a laptop, a tablet, a mobile device, a smart device, thin client, etc.), or through a combination of both hardware and software. For example, some or all components of the system 100 may be implemented using discrete circuitry devices and/or using one or more processors (e.g., audio processor and/or digital signal processor) executing program code stored in a memory (not shown), the program code being configured to carry out one or more processes or operations described herein, such as, for example, the method 400 shown in FIG. 4. Thus, in embodiments, the system 100 may include one or more processors, memory devices, computing devices, and/or other hardware components not shown in the figures.

All or portions of the processes described herein, including method 400 of FIG. 4, may be performed by one or more processing devices or processors (e.g., analog to digital converters, encryption chips, etc.) that are within or external to the corresponding conferencing system (e.g., system 100 of FIG. 1). In addition, one or more other types of components (e.g., memory, input and/or output devices, transmitters, receivers, buffers, drivers, discrete components, logic circuits, etc.) may also be used in conjunction with the processors and/or other processing components to perform any, some, or all of the steps of the method 400. As an example, in some embodiments, each of the methods described herein may be carried out by a processor executing software stored in a memory. The software may include, for example, program code or computer program modules comprising software instructions executable by the processor. In some embodiments, the program code may be a computer program stored on a non-transitory computer readable medium that is executable by a processor of the relevant device.

The terms “non-transitory computer-readable medium” and “computer-readable medium” include a single medium or multiple media, such as a centralized or distributed database, and/or associated caches and servers that store one or more sets of instructions. Further, the terms “non-transitory computer-readable medium” and “computer-readable medium” include any tangible medium that is capable of storing, encoding or carrying a set of instructions for execution by a processor or that cause a system to perform any one or more of the methods or operations disclosed herein. As used herein, the term “computer readable medium” is expressly defined to include any type of computer readable storage device and/or storage disk and to exclude propagating signals.

Any process descriptions or blocks in figures should be understood as representing modules, segments, or portions of code which include one or more executable instructions for implementing specific logical functions or steps in the process, and alternate implementations are included within the scope of the embodiments of the invention in which functions may be executed out of order from that shown or discussed, including substantially concurrently or in reverse order, depending on the functionality involved, as would be understood by those having ordinary skill in the art.

Any of the processors described herein may include a general purpose processor (e.g., a microprocessor) and/or a special purpose processor (e.g., an audio processor, a digital signal processor, etc.). In some examples, the processor(s) described herein may be any suitable processing device or set of processing devices such as, but not limited to, a microprocessor, a microcontroller-based platform, an integrated circuit, one or more field programmable gate arrays (FPGAs), and/or one or more application-specific integrated circuits (ASICs).

Any of the memories or memory devices described herein may be volatile memory (e.g., RAM including non-volatile RAM, magnetic RAM, ferroelectric RAM, etc.), non-volatile memory (e.g., disk memory, FLASH memory, EPROMs, EEPROMs, memristor-based non-volatile solid-state memory, etc.), unalterable memory (e.g., EPROMs), read-only memory, and/or high-capacity storage devices (e.g., hard drives, solid state drives, etc.). In some examples, the memory described herein includes multiple kinds of memory, particularly volatile memory and non-volatile memory.

Moreover, any of the memories described herein may be computer readable media on which one or more sets of instructions can be embedded. The instructions may reside completely, or at least partially, within any one or more of the memory, the computer readable medium, and/or within one or more processors during execution of the instructions. In some embodiments, the memory described herein may include one or more data storage devices configured for implementation of a persistent storage for data that needs to be stored and recalled by the end user. In such cases, the data storage device(s) may save data in flash memory or other memory devices. In some embodiments, the data storage device(s) can be implemented using, for example, SQLite data base, UnQLite, Berkeley DB, BangDB, or the like.

Any of the computing devices described herein can be any generic computing device comprising at least one processor and a memory device. In some embodiments, the computing device may be a standalone computing device included in the audio system 100, or may reside in another component of the system 100, such as, e.g., any one of the microphone 102, the localizer 104, the automatic lobe deployer 106, and/or the lobe gain controller 108. In such embodiments, the computing device may be physically located in and/or dedicated to the given environment or room, such as, e.g., the same environment in which the microphone 102 is located. In other embodiments, the computing device may not be physically located in proximity to the microphone 102 but may reside in an external network, such as a cloud computing network, or may be otherwise distributed in a cloud-based environment. Moreover, in some embodiments, the computing device may be implemented with firmware or completely software-based as part of a network, which may be accessed or otherwise communicated with via another device, including other computing devices, such as, e.g., desktops, laptops, mobile devices, tablets, smart devices, etc. Thus, the term “computing device” should be understood to include distributed systems and devices (such as those based on the cloud), as well as software, firmware, and other components configured to carry out one or more of the functions described herein. Further, one or more features of the computing device may be physically remote and may be communicatively coupled to the computing device.

In some embodiments, any of the computing devices described herein may include one or more components configured to facilitate a conference call, meeting, classroom, or other event and/or process audio signals associated therewith to improve an audio quality of the event. For example, in various embodiments, any computing device described herein may comprise a digital signal processor (“DSP”) configured to process the audio signals received from the various microphones or other audio sources using, for example, automatic mixing, matrix mixing, delay, compressor, parametric equalizer (“PEQ”) functionalities, acoustic echo cancellation, and more. In other embodiments, the DSP may be a standalone device operatively coupled or connected to the computing device using a wired or wireless connection. One exemplary embodiment of the DSP, when implemented in hardware, is the P300 IntelliMix Audio Conferencing Processor from SHURE, the user manual for which is incorporated by reference in its entirety herein. As further explained in the P300 manual, this audio conferencing processor includes algorithms optimized for audio/video conferencing applications and for providing a high quality audio experience, including eight channels of acoustic echo cancellation, noise reduction and automatic gain control. Another exemplary embodiment of the DSP, when implemented in software, is the IntelliMix Room from SHURE, the user guide for which is incorporated by reference in its entirety herein. As further explained in the IntelliMix Room user guide, this DSP software is configured to optimize the performance of networked microphones with audio and video conferencing software and is designed to run on the same computer as the conferencing software. In other embodiments, other types of audio processors, digital signal processors, and/or DSP software components may be used to carry out one or more of audio processing techniques described herein, as will be appreciated.

Moreover, any of the computing devices described herein may also comprise various other software modules or applications (not shown) configured to facilitate and/or control the conferencing event, such as, for example, internal or proprietary conferencing software and/or third-party conferencing software (e.g., Microsoft Skype, Microsoft Teams, Bluejeans, Cisco WebEx, GoToMeeting, Zoom, Join.me, etc.). Such software applications may be stored in the memory of the computing device and/or may be stored on a remote server (e.g., on premises or as part of a cloud computing network) and accessed by the computing device via a network connection. Some software applications may be configured as a distributed cloud-based software with one or more portions of the application residing in the computing device and one or more other portions residing in a cloud computing network. One or more of the software applications may reside in an external network, such as a cloud computing network. In some embodiments, access to one or more of the software applications may be via a web-portal architecture, or otherwise provided as Software as a Service (SaaS).

In general, a computer program product in accordance with embodiments described herein includes a computer usable storage medium (e.g., standard random access memory (RAM), an optical disc, a universal serial bus (USB) drive, or the like) having computer-readable program code embodied therein, wherein the computer-readable program code is adapted to be executed by a processor (e.g., working in connection with an operating system) to implement the methods described herein. In this regard, the program code may be implemented in any desired language, and may be implemented as machine code, assembly code, byte code, interpretable source code or the like (e.g., via C, C++, Java, ActionScript, Python, Objective-C, JavaScript, CSS, XML, and/or others). In some embodiments, the program code may be a computer program stored on a non-transitory computer readable medium that is executable by a processor of the relevant device.

It should be noted that in the description and drawings, like or substantially similar elements may be labeled with the same reference numerals. However, sometimes these elements may be labeled with differing numbers, such as, for example, in cases where such labeling facilitates a more clear description. Additionally, the drawings set forth herein are not necessarily drawn to scale, and in some instances proportions may have been exaggerated to more clearly depict certain features. Such labeling and drawing practices do not necessarily implicate an underlying substantive purpose. As stated above, the specification is intended to be taken as a whole and interpreted in accordance with the principles of the invention as taught herein and understood to one of ordinary skill in the art.

In this disclosure, the use of the disjunctive is intended to include the conjunctive. The use of definite or indefinite articles is not intended to indicate cardinality. In particular, a reference to “the” object or “a” and “an” object is intended to also denote one of a possible plurality of such objects.

This disclosure describes, illustrates and exemplifies one or more particular embodiments of the invention in accordance with its principles. The disclosure is intended to explain how to fashion and use various embodiments in accordance with the technology rather than to limit the true, intended, and fair scope and spirit thereof. That is, the foregoing description is not intended to be exhaustive or to be limited to the precise forms disclosed herein, but rather to explain and teach the principles of the invention in such a way as to enable one of ordinary skill in the art to understand these principles and, with that understanding, be able to apply them to practice not only the embodiments described herein, but also other embodiments that may come to mind in accordance with these principles. The embodiment(s) provided herein were chosen and described to provide the best illustration of the principle of the described technology and its practical application, and to enable one of ordinary skill in the art to utilize the technology in various embodiments and with various modifications as are suited to the particular use contemplated. All such modifications and variations are within the scope of the embodiments as determined by the appended claims, as may be amended during the pendency of this application for patent, and all equivalents thereof, when interpreted in accordance with the breadth to which they are fairly, legally and equitably entitled.

What is claimed is:

1. A method performed by one or more processors in communication with at least one microphone, the method comprising:
receiving, from the at least one microphone, sound location information for an audio source detected by the at least one microphone;
calculating a distance between the audio source and the at least one microphone based on the sound location information, a first height associated with the at least one microphone, and a second height associated with the audio source;
determining, based on the distance, a gain value for an audio pickup lobe directed towards the audio source by the at least one microphone; and
applying the gain value to an audio channel of the at least one microphone, the audio channel configured to receive audio signals captured using the audio pickup lobe.

2. The method of claim 1, wherein determining a gain value for the audio pickup lobe comprises:
selecting one of a plurality of gain parameters based on the distance; and
calculating the gain value based on the selected gain parameter.

3. The method of claim 2, wherein the plurality of gain parameters comprises a minimum parameter for setting the gain value to a minimum value, a maximum parameter for setting the gain value to a maximum value, and a medium parameter for using a ratio to set the gain value.

4. The method of claim 3, wherein selecting one of the plurality of gain parameters comprises selecting the minimum parameter if the distance is equal to or less than a lower threshold, selecting the maximum parameter if the distance is equal to or greater than an upper threshold, and selecting the medium parameter if the distance is between the lower threshold and the upper threshold.

5. The method of claim 4, further comprising determining the lower threshold based on the first height and the second height.

6. The method of claim 4, further comprising determining the upper threshold based on the first height.

7. The method of claim 1, further comprising:
selecting, based on the sound location information received from the at least one microphone, one of the following actions: deployment of a new audio pickup lobe, resetting of an existing audio pickup lobe, or repositioning of an existing audio pickup lobe; and
based on a selection of the deployment action or the resetting action, proceeding with calculating the distance.

8. The method of claim 1, further comprising:
determining, based on the sound location information, a set of coordinates representing an estimated location of the audio source; and
using the set of coordinates to direct the audio pickup lobe towards the audio source.

9. A system comprising:
at least one microphone configured to detect an audio source and determine sound location information for the audio source; and
one or more processors communicatively coupled to the at least one microphone, the one or more processors configured to:
receive the sound location information from the at least one microphone;
calculate a distance between the audio source and the at least one microphone based on the sound location information, a first height associated with the at least one microphone, and a second height associated with the audio source;
determine, based on the distance, a gain value for an audio pickup lobe directed towards the audio source by the at least one microphone; and
apply the gain value to an audio channel of the at least one microphone, the audio channel configured to receive audio signals captured using the audio pickup lobe.

10. The system of claim 9, wherein the one or more processors are configured to determine the gain value for the audio pickup lobe by:
selecting one of a plurality of gain parameters based on the distance; and
calculating the gain value based on the selected gain parameter.

11. The system of claim 10, wherein the plurality of gain parameters comprises a minimum parameter for setting the gain value to a minimum value, a maximum parameter for setting the gain value to a maximum value, and a medium parameter for using a ratio to set the gain value.

12. The system of claim 11, wherein the one or more processors are configured to select one of the plurality of gain parameters by:
selecting the minimum parameter if the distance is equal to or less than a lower threshold;
selecting the maximum parameter if the distance is equal to or greater than an upper threshold; and
selecting the medium parameter if the distance is between the lower threshold and the upper threshold.

13. The system of claim 12, wherein the one or more processors are further configured to determine the lower threshold based on the first height and the second height.

14. The system of claim 12, wherein the one or more processors are further configured to determine the upper threshold based on the first height.

15. The system of claim 9, wherein the one or more processors are further configured to:
select, based on the sound location information received from the at least one microphone, one of the following actions: deployment of a new audio pickup lobe, resetting of an existing audio pickup lobe, or repositioning of an existing audio pickup lobe; and
based on a selection of the deployment action or the resetting action, proceed with calculating the distance.

16. The system of claim 9, wherein the one or more processors are further configured to:
determine, based on the sound location information, a set of coordinates representing an estimated location of the audio source; and
use the set of coordinates to direct the audio pickup lobe towards the audio source.

17. A non-transitory computer-readable medium comprising instructions that, when executed by one or more processors in communication with at least one microphone, cause the one or more processors to perform:
receive, from the at least one microphone, sound location information for an audio source detected by the at least one microphone;
calculate a distance between the audio source and the at least one microphone based on the sound location information, a first height associated with the at least one microphone, and a second height associated with the audio source;
determine, based on the distance, a gain value for an audio pickup lobe directed towards the audio source by the at least one microphone; and
apply the gain value to an audio channel of the at least one microphone, the audio channel configured to receive audio signals captured using the audio pickup lobe.

18. The non-transitory computer-readable medium of claim 17 further comprising instructions that cause the one or more processors to determine the gain value for the audio pickup lobe by:
selecting one of a plurality of gain parameters based on the distance; and
calculating the gain value based on the selected gain parameter.

19. The non-transitory computer-readable medium of claim 17 further comprising instructions that cause the one or more processors to perform:
select, based on the sound location information received from the at least one microphone, one of the following actions: deployment of a new audio pickup lobe, resetting of an existing audio pickup lobe, or repositioning of an existing audio pickup lobe; and
based on a selection of the deployment action or the resetting action, proceed with calculating the distance.

20. The non-transitory computer-readable medium of claim 17 further comprising instructions that cause the one or more processors to perform:
determine, based on the sound location information, a set of coordinates representing an estimated location of the audio source; and
use the set of coordinates to direct the audio pickup lobe towards the audio source.
